(19) United States
(12) Patent Application Publication
(10) Pub. No.: US 2026/0320457 A1
(43) Pub. Date: Oct. 15, 2026

(54) ARRANGEMENT AND METHOD FOR TUNING A QUANTUM DEVICE

(71) Applicant: IQM FINLAND OY, Espoo (FI)

(72) Inventors: Ugur YILMAZ, Munich (DE); Olli-Pentti SAIRA, Espoo (FI); Jayshankar NATH, Munich (DE)

(21) Appl. No.: 19/113,704

(22) PCT Filed: Sep. 21, 2022
(86) PCT No.: PCT/FI2022/050635

§ 371 Date: Mar. 20, 2025

(51) Int. Cl. G06N 10/40; H10N 50/00; H10N 60/12

(52) U.S. Cl. CPC G06N 10/40; H10N 50/00; H10N 60/12

(57) ABSTRACT

Various example embodiments relate to an arrangement for frequency tuning at least one quantum device. The arrangement may comprise a frequency tuning element. The frequency tuning element may be configured to adjust an orientation of a magnetization of a magnetic free layer, thereby adjusting the strength of the magnetic flux through the quantum device and causing the operational frequency of the quantum device to shift.

### FIELD OF THE INVENTION

The present disclosure relates to quantum computing. More particularly, the present disclosure relates to an arrangement and a method for tuning a quantum device. Additionally, the present disclosure relates to a quantum computing system.

### BACKGROUND OF THE INVENTION

One of the methods of tuning quantum devices, such as qubits and tunable couplers, is by using a magnetic flux. These are generally applied using individual flux lines for each quantum device. However, such an architecture is not scalable and can degrade the performance of the Quantum Processing Unit (QPU) due to flux cross-talks. Moreover, the dephasing time (T2*) may also be limited by the flux noise.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an objective to provide an arrangement and a method for tuning a quantum device, and a quantum computing system. The foregoing and other objectives are achieved by the features of the independent claims. Further implementation forms are apparent from the dependent claims, the description, and the figures.

According to a first aspect, an arrangement for frequency tuning at least one quantum device, wherein the arrangement comprises a frequency tuning element, wherein the frequency tuning element is configured to generate a magnetic flux through the quantum device, characterized in that the frequency tuning element comprises: a spintronic device, wherein the spintronic device comprises a magnetic free layer, wherein the frequency tuning element is configured to adjust an orientation of a magnetization of the magnetic free layer, thereby adjusting the strength of the magnetic flux through the quantum device, and causing the operational frequency of the quantum device to shift.

According to an example embodiment of the first aspect, the spintronic device comprises a magnetic memory element.

According to an example embodiment of the first aspect, the spintronic device comprises a magnetic fixed layer separated from the magnetic free layer.

According to an example embodiment of the first aspect, the arrangement further comprising a frequency tuning unit, and at least one tuning line coupled to the spintronic device, wherein the frequency tuning unit is configured to apply a non-persistent signal to the spintronic device via the tuning line to adjust the orientation of the magnetization of the magnetic free layer, thereby adjusting the strength of the magnetic flux through the quantum device, and causing the operational frequency of the quantum device to shift.

According to an example embodiment of the first aspect, the spintronic device comprises a Magnetic Josephson Junction—MJJ—, wherein the arrangement further comprises a global flux line connected to a constant current source, and wherein the frequency tuning element comprises a current divider of the global flux line, the current divider comprising a first branch and a second branch, wherein the first branch comprises an inductive element coupled to the quantum device such that a flux current going through the inductive element generates the magnetic flux through the quantum device, and the second branch comprises the MJJ, wherein the tuning line is magnetically coupled to the MJJ, wherein the frequency tuning unit is configured to apply a non-persistent magnetic field to the MJJ via the tuning line to adjust the orientation of the magnetization of the magnetic free layer, thereby adjusting a current that passes through the MJJ, thereby adjusting the flux current going through the inductive element, thereby adjusting the strength of the magnetic flux through the quantum device, and causing the operational frequency of the quantum device to shift.

According to an example embodiment of the first aspect, the arrangement comprising a plurality of global flux lines, wherein a plurality of frequency tuning elements is serially connected to each global flux line.

According to an example embodiment of the first aspect, the magnetic free layer is an in-plane magnetised isotropically coercive layer to provide memristive behaviour.

According to an example embodiment of the first aspect, the magnetic free layer is made from a granular media to provide memristive behaviour.

According to an example embodiment of the first aspect, the inductive element is coupled to the quantum device via a flux transformer.

According to an example embodiment of the first aspect, the inductive element and the quantum device are placed on opposite sides of a substrate, the inductive element and the quantum device are placed on a same side of a substrate; or the inductive element and the quantum device are placed on two different substrates, wherein the inductive element and the quantum device are optionally coupled via a galvanic link.

According to an example embodiment of the first aspect, the MJJ is placed in series with a shunt resistor.

According to an example embodiment of the first aspect, the spintronic device is configured to generate the magnetic flux through the quantum device (101), wherein the frequency tuning unit is configured to apply a non-persistent current to the spintronic device via the tuning line to adjust the orientation of the magnetization of the magnetic free layer, thereby adjusting the strength of the magnetic flux through the quantum device, and causing the operational frequency of the quantum device to shift.

According to an example embodiment of the first aspect, the magnetic free layer is made from a granular media to provide memristive behavior.

According to an example embodiment of the first aspect, the spintronic device is configured to adjust the orientation of the magnetization of the magnetic free layer via spin-transfer torque effect.

According to an example embodiment of the first aspect, the spintronic device is configured to adjust the orientation of the magnetization of the magnetic free layer via spin-orbit torque effect.

According to an example embodiment of the first aspect, the spintronic device is configured to adjust the orientation of the magnetization of the magnetic free layer via domain wall motion in the free layer.

According to an example embodiment of the first aspect, the spintronic device is a magnetic spin valve.

According to an example embodiment of the first aspect, the spintronic device is a magnetic tunnel junction —MTJ—.

According to an example embodiment of the first aspect, the spintronic device and the quantum device are placed on opposite sides of a substrate; the spintronic device and the quantum device are placed on a same side of a substrate; or the spintronic device and the quantum device are placed on two different substrates, wherein the spintronic device and the quantum device are optionally coupled via a galvanic link.

According to an example embodiment of the first aspect, the quantum device and the spintronic device are coupled via a flux transformer.

According to an example embodiment of the first aspect, the at least one quantum device comprises one or more of at least one qubit or at least one tunable coupler.

According to a second aspect, a quantum computing system may comprise a plurality of quantum devices, and at least an arrangement according to any embodiments of the first aspect for tuning the operational frequency of at least one of the quantum devices.

According to an example embodiment of the second aspect, the quantum computing system further comprises a global magnetic field coil configured to reset one or more of the spintronic devices.

According to an example embodiment of the second aspect, said plurality of quantum devices form an array, and; the spintronic device of each frequency tuning element is coupled to at least two tuning lines, and wherein the tuning lines of all the frequency tuning elements are placed in a cross-bar architecture.

According to a third aspect, a method for frequency tuning one or more quantum devices in a quantum computing system according to any embodiments of the second aspect, the method comprising: adjusting the orientation of magnetization of the magnetic free layer, thereby adjusting the strength of the magnetic flux through the quantum device and causing the operational frequency of the quantum device to shift.

Some embodiments facilitate tuning of a quantum device without requiring a persistent tuning signal. In particular, some embodiments can tune and maintain an operational frequency of a quantum device without the crosstalk and/or heating that would be generated by a persistent tuning signal. Some embodiments facilitate tuning of a quantum device in situ and in real-time. Some embodiments can facilitate such tuning by leveraging a tunable spintronic device.

Some embodiments may be arranged in a cross-bar architecture. This can reduce the number of tuning lines. Thus, crosstalk and/or heating can be further reduced. This enables QPU scaling with/without the use of Single-Flux Quantum (SFQ) elements.

Some embodiments facilitate flux tuning capability without QPU heating. In particular, some embodiments do not require raising the temperature either globally or locally. This enables continuous operation of the QPU.

Some embodiments are compatible with standard CMOS compatible fabrication process. This facilitates industrial fabrication.

### BRIEF DESCRIPTION OF THE DRAWINGS

In the following, example embodiments are described in more detail with reference to the attached figures and drawings, in which:

FIG. 1 illustrates one quantum device and an example of an arrangement for frequency tuning the quantum device;

FIG. 2 illustrates one quantum device and an example of an arrangement for frequency tuning the quantum device comprising an MJJ;

FIG. 3 illustrates an example MJJ;

FIG. 4 illustrates an example arrangement for frequency tuning a plurality of quantum devices;

FIG. 5 illustrates an example quantum computing system;

FIG. 6 illustrates one quantum device and an example of an arrangement for frequency tuning the quantum device comprising a spintronic device;

FIG. 7 illustrates an example spintronic device;

FIG. 8 illustrates an example quantum computing system.

FIG. 9 illustrates a schematic representation of a tuning unit according to an embodiment.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilised, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

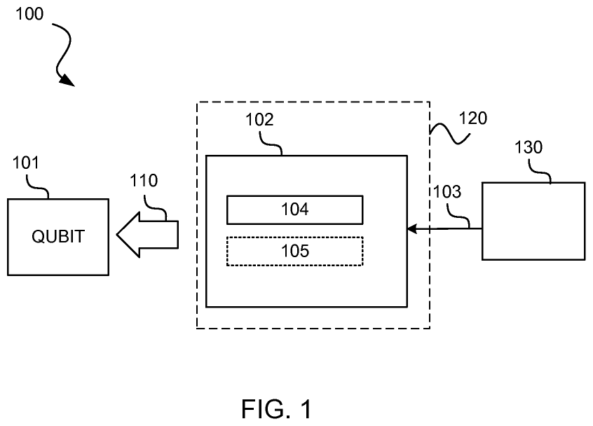

FIG. 1 illustrates a schematic representation of an arrangement for quantum computing according to an embodiment.

In various embodiments, the arrangement 100 for quantum computing comprises at least one quantum device 101 and at least one frequency tuning element 120.

In various cases, the quantum devices in an arrangement for quantum computing can require frequency tuning. In particular, the quantum devices can require individualized frequency tuning so as to achieve individualized operational frequencies. For example, small fabrication discrepancies between the quantum devices and other quantum computing unit elements and changing environmental conditions can require in-situ tuning.

For example, quantum devices can require frequency tuning for setting the idling frequency, changing the frequency to perform quantum gates and/or operations (e. g., two qubit gates), tuning the interaction between two qubits ON and OFF (e.g., in case of tunable couplers), etc.

In various cases, it can be desirable to shift the operational frequency of the quantum device 101 to a different value. In various embodiments, the frequency tuning element 120 can be used to facilitate this shift.

In some embodiments, the quantum device 101 and the frequency tuning element 120 can be arranged on a same substrate or on different substrates.

In some embodiments, the arrangement 100 may comprise one frequency tuning element 120 for each quantum device 101. In some embodiments, a frequency tuning element 120 may be configured to tune the frequency of a plurality of quantum devices 101.

The quantum device 101 may be any suitable quantum device on which flux tuning can be performed. In particular, a quantum device 101 may be a qubit or a tunable coupler. A tunable coupler may be an element between two qubits that is used to turn the interaction between the two qubits ON or OFF.

According to some embodiments, the at least one quantum device 101 comprises at least one superconducting quantum device. The quantum device may comprise any type of quantum devices, such as a tunable coupler or a qubit.

According to some embodiments, the at least one quantum device 101 comprises at least one Josephson junction. According to some embodiments, the at least one quantum device 101 comprises a transmon quantum device. Alternatively, the at least one quantum device 101 may comprise any other type of quantum device, such as, a flux quantum device, a charge quantum device, a phase quantum device, or a fluxonium quantum device.

Although some embodiments may be disclosed herein with reference to a certain type of quantum device, these quantum device types are only exemplary. In any embodiment disclosed herein, the at least one quantum device 101 may be implemented in various ways and using various technologies.

The quantum device 101 has an operational frequency that is based on an external magnetic flux to which the quantum device 101 is exposed.

The quantum device may be, for example, a superconducting qubit, such as transmon qubit, a flux qubit, a charge qubit, a phase qubit, or a fluxonium qubit, or any other other kind of flux tunable qubit. For example, the quantum device 101 can be a superconducting quantum interference device (SQUID). In particular, the quantum device 101 may comprise at least two Josephson Junctions coupled in parallel. In such case, the overall operational frequency of the SQUID loop can be a function of an external magnetic flux passing through the loop (e.g., passing between the parallel Josephson Junctions).

As shown on FIG. 1, the frequency tuning element 120 is configured to generate a magnetic field that induces a magnetic flux 110 through the quantum device 101. The operational frequency of the quantum device 101 can be adjusted, shifted, and/or modulated by controlling the strength of the magnetic flux 110 through the quantum device 101.

In various embodiments, the magnetic field is tunable, in the sense that it can be adjusted to a required strength by applying a tuning signal. In various embodiments, the magnetic field is persistent, in the sense that it continues to exist after the tuning signal is applied.

In various embodiments, the frequency tuning element 120 comprises a spintronic device 102. A spintronic device may be any suitable device that allows the electron spin degree of freedom to be manipulated, in addition to its charge. This enables the manipulation of the magnetic moment of the spintronic device via its charge and vice-versa due to spin-charge coupling. Examples of a spintronic device include a Magnetic Josephson Junction (MJJ), a magnetic tunnel junction (MTJ), a spin valve (SV), and a single magnetic layer.

The spintronic device 102 may comprise a magnetic memory element. The magnetic memory element may be any suitable device that exhibits magnetic remanence. In particular, the magnetic memory element may be any suitable device that can maintain magnetization after a magnetic field is applied.

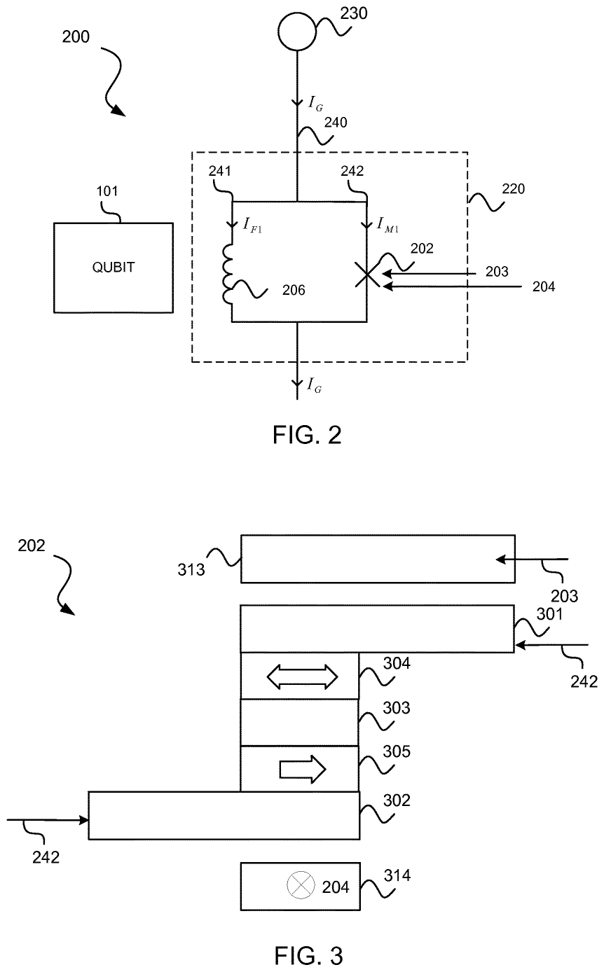

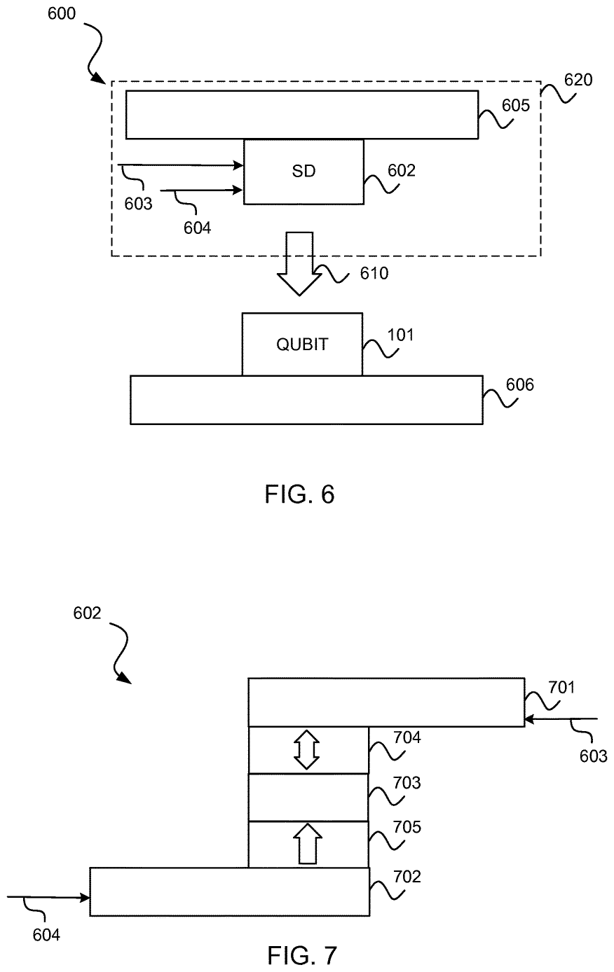

In some embodiments, the spintronic device 102, may be a Magnetic Josephson Junction (MJJ), as described in more detail in relation to FIGS. 2 to 5. In some embodiments, the spintronic device 102 may be a magnetic tunnel junction (MTJ), or a spin valve (SV), as described in more detail in relation to FIGS. 6 to 8.

The spintronic device 102 comprises a magnetic free layer 104. In some embodiments, the spintronic device 102 comprises a magnetic free layer 104 and a magnetic fixed layer 105. The magnetic free layer 104 and magnetic fixed layer 105 may be made of ferromagnetic or ferrimagnetic material, or any other suitable magnetic material.

The strength of the magnetic flux 110 through the quantum device 101 depends on an orientation of magnetization of the magnetic free layer 104, or a relative orientation of the magnetic free layer 104 and magnetic fixed layer 105. In various embodiments, the strength of the magnetic flux 110 through the quantum device 101 can be adjusted by adjusting the orientation of magnetization of the magnetic free layer 104, or the relative orientation of the magnetic free layer 104 and the magnetic fixed layer 105.

In some embodiments, the spintronic device 102 is coupled to at least one tuning line 103. A tuning signal can be applied to the spintronic device 102 via the tuning line 103. The tuning signal may be an electromagnetic signal. In particular, the tuning signal may be embodied in an electric current or a magnetic field.

The arrangement 100 may further comprise a frequency tuning unit 130 for providing the tuning signal 103 to the frequency tuning element 120. In some embodiments, the arrangement 100 may comprise one frequency tuning unit 130 for each of the quantum devices 101. In some embodiments, a frequency tuning unit 130 may be configured to tune the frequency of a plurality of quantum devices 101. In some embodiments, the tuning unit 130 may be implemented together with a control unit of one or more quantum devices 101 as a single device.

Although the embodiment of FIG. 1 illustrates only one tuning line originating from the frequency tuning unit 130, this is only for clarity of illustration. There may be any number of tuning lines originating from the frequency tuning unit 130.

The operational frequency of the quantum device 101 can be adjusted by feeding the tuning signal into the tuning line 103. More specifically, the orientation of the magnetization of the magnetic layer 104 (e.g., the relative orientation of the magnetization of the magnetic layers 104 and 105) can be adjusted by feeding the tuning signal into the tuning line 103. As a result, the strength of the magnetic flux 110 through the quantum device 101 is adjusted to the required value. This causes the operational frequency of the quantum device 101 to shift from an initial value to a modified value. This may be referred to a flux tuning, where the magnetic flux 110 through the quantum device 101 causes the operational frequency of the quantum device 101 to shift.

In some embodiments, the tuning signal can be non-persistent, in the sense that it is lasting or acting for only a limited period of time, that can be referred as an active time. In particular, the active time of the tuning signal may be shorter than an active time of the magnetic field. In other words, the magnetic field continues to exist after the tuning signal is applied.

In some embodiments, the strength of the magnetic flux 110 through the quantum device 101 can be maintained at the adjusted value after the non-persistent tuning signal is applied (e.g., after the active time of the non-persistent tuning signal). This is because the frequency tuning element 120 comprises a spintronic device 102 that can retain its magnetic properties after a tuning signal is applied. Thus, in various embodiments, the frequency tuning element 120 can shift the operational frequency of the quantum device 101 from the initial value to the required value and maintain the operational frequency of the quantum device 101 at the required value after the non-persistent tuning signal is applied. Thus, the operational frequency of the quantum device can be maintained without the crosstalk and/or heating that would be generated by a persistent tuning signal.

As illustrated by FIG. 2, in various embodiments, the spintronic device 102 comprises a Magnetic Josephson Junction—MJJ—202. FIG. 2 illustrates a schematic representation of a quantum device and a frequency tuning element according to an embodiment.

The arrangement 200 further comprises a global flux line 240. The global flux line 240 may be connected to a constant current source 230, such that a persistent global current I_{G} flows through the global flux line 240.

The frequency tuning 220 unit comprises a current divider of the global flux line 240. The current divider scales the persistent global current I_{G} into a flux current I_{F}. The flux current I_{F} can further be adjusted by tuning the MJJ 202.

More specifically, the global flux line 230 branches into a first branch 241 and a second branch 242. The first and second branches are then closed back into the global flux line 240. As such, the global current I_{G} flowing through the global flux line 240 is divided into a first current going through the first branch 241 and a second current going through the second branch 242.

The first branch 241 comprises an inductive element 206 coupled to the quantum device 101. The first current going through the first branch 241 is equal to a flux current I_{F} going through the inductive element 206. The flux current I_{F} induces the magnetic flux 210 through the quantum device 101.

The inductive element 206 can be coupled to the quantum device 101 either directly or via a flux transformer and/or a flip chip design. A flux transformer and/or flip chip design can increase the distance between the quantum device 101 and the MJJ 202 and therefore reduce the influence of any stray fields arising from the MJJ 202 on the quantum device 101.

The inductive element 206 and the quantum device 101 may be placed on a same side of a substrate. The inductive element 206 and the quantum device 101 may be placed on opposite sides of a substrate. The inductive element 206 and the quantum device 101 may also be placed on two different substrates in a flip-chip design, to reduce magnetic stray fields.

The second branch 242 comprises the MJJ 202. The second current going through the second branch 242 is equal to a current I_{M} that passes through the MJJ 202. As described in more detail in relation to FIG. 3, the current I_{M} that passes through the MJJ depends on the orientation of the magnetization of the magnetic free layer 104 (e.g., the relative orientation of the magnetization of the magnetic layers 104 and 105).

The current in the first branch 241 (and therefore the flux current I_{F} going through the inductive element 206) evolves with the current in the second branch 242 (and therefore the current I_{M} that passes through the MJJ 202). More specifically, keeping the global current I_{G} constant, if the current in the second branch 242 is increased, the current in the first branch 241 is consequently decreased. Inversely, if the current in the second branch 242 is decreased, the current in the first branch 241 is consequently increased.

Such an arrangement creates a current-divider circuit, where the flux current I_{F} depends on the state of the MJJ 202. Since the MJJ 202 retains its magnetic properties, the MJJ 202 needs to be tuned only once when the frequency of the quantum device 101 needs to be changed.

The MJJ 202 is magnetically coupled to at least one tuning line (e.g., tuning lines 203 and 204).

As described by Oersted's law, a current applied via the tuning lines 203 and/or 204 generates a magnetic field. The generated magnetic field interacts with the free layer of the MJJ 304. This interaction leads to the rotation of the magnetisation of the free layer depending on the Zeeman energy. The current applied via the tuning lines 203 and/or 204 are optimised to rotate the free layer by the required amount. In particular, the current applied via the tuning lines 203 and/or 204 depends on amplitude and duration of current and distance of the lines from the free layer.

The tuning signal can be applied to the MJJ 202 as a non-persistent magnetic field generated by a current flowing through the tuning lines 203 and/or 204. By applying the non-persistent magnetic field to the MJJ 202, the strength of the magnetic flux 210 through the quantum device can be adjusted, thereby causing the frequency of the quantum device 101 to shift.

More specifically, the frequency of the quantum device 101 can be adjusted from an initial value to a desired value by tuning the MJJ 202. The MJJ 202 can be tuned by applying a non-persistent magnetic field to the MJJ 202 through the tuning lines 203 and/or 204. Consequently, the current I_{M} that passes through the MJJ 202 (and therefore the current in the second branch 242) is adjusted. The current in the first branch 241 (and therefore the flux current I_{F} going through the inductive element 206) is consequently adjusted. The strength of the magnetic flux 210 through the quantum device 101 is consequently adjusted to a required value. This causes the operational frequency of the quantum device 101 to shift from the initial value to the required value.

The MJJ 202 exhibits memristive behaviour in the sense that it is continuously tunable and can retain its state of internal resistance. The magnetic properties of MJJ 202 can be tuned to and retained at any value within a range. Thus, the magnetic flux 210 through the quantum device 101 can be maintained at the adjusted strength after the non-persistent tuning signal is applied. Thus, the frequency tuning element 220 can shift the operational frequency of the quantum device 101 from the initial value to the required value and maintain the operational frequency of the quantum device 101 at the required value after the non-persistent tuning signal is applied and turned off. The required value can be any value within a range of frequencies.

FIG. 3 illustrates a schematic representation of the MJJ 202 according to an embodiment.

The MJJ 202 comprises a magnetic free layer 304 and a magnetic fixed layer 305. The magnetic layers 304 and 305 are separated by a barrier 303, also called weak link. The barrier 303 can be a thin insulating barrier (e.g., thin oxide layer), or a thin layer of non-super-conducting metal, also called normal metal. The magnetic layers 304 and 305 and the barrier 303 form a Josephson junction.

The MJJ 202 further comprises a first set of two metallic (e.g., superconducting) electrodes 301, 302 connected via the Josephson junction. The electrodes 301, 302 are each connected to the second branch 242, completing the circuit of the second branch 242. The MJJ 202 further comprises a second set of electrodes 313, 314. Electrodes 313, 314 are orthogonal to each other and electrically separated from the rest of the MJJ 202. Electrodes 313 and 314 are in turn connected to the tuning lines 203 and 204 respectively. A current applied through tuning lines 203 and 204 is magnetically coupled to the magnetic free layer 304, causing its magnetisation to rotate in plane by the required amount.

The orientation of the magnetization of the magnetic layer 304 (e.g., the relative orientation of the magnetization of the magnetic layers 304 and 305) determines the resistance of the MJJ 202, and therefore the strength of the current I_{M} flowing through the MJJ 202.

The MJJ 202 is tunable in the sense that the resistance of the MJJ 202 can be adjusted. The MJJ tuning can be performed by applying a magnetic field to the MJJ 202 via a current applied to the electrodes 313, 312. Consequently, the relative orientation of magnetization the layers 304 and 305, and therefore the resistance of the MJJ 202, and therefore the current I_{M} that passes through the MJJ 202 is correspondingly adjusted.

The MJJ 202 exhibits memristic behaviour in the sense that its resistance can be tuned continuously, and this state can be retained based on the history of applied magnetic field. Any technique may be used to provide memristic behaviour to the MJJ.

For example, the magnetic free layer 304 may be an isotropically coercive layer, and in particular an in-plane magnetised isotropically coercive layer. Such an isotropically coercive free layer can provide memristic behavior, as for example described in M. Mansueto et. al., “Spintronic memristors for neuromorphic circuits based on the angular variation of tunnel mag-netoresistance” Nanoscale 13, 11488, 2021.

As another example, the magnetic free layer 304 may be made from a granular media. Such a granular free layer can provide memristic behavior, as for example described in in M. Mansueto, “Memristic magnetic memory for spintronic synapses,” Universite Grenoble Alpes, 2020.

Magnetic stray fields arising from the MJJ 202 can be reduced by the use of synthetic antimagnetic layers as the magnetic layers of the MJJ 202.

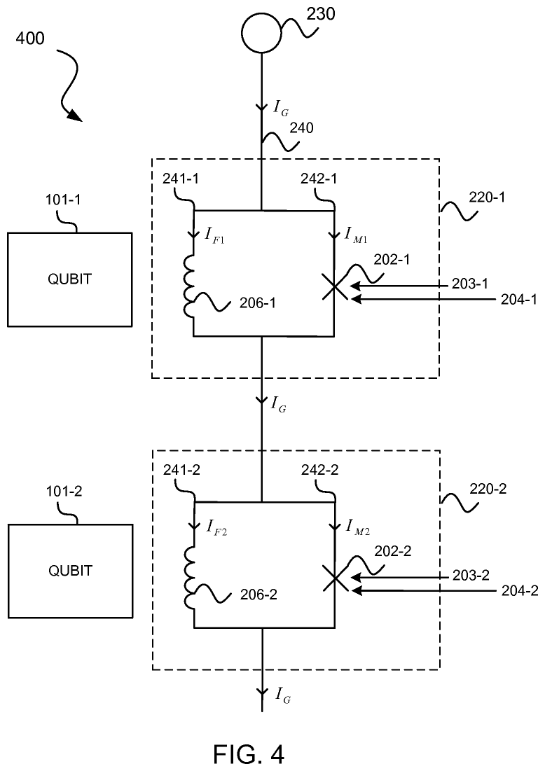

As illustrated by FIG. 4, a plurality of frequency tuning elements 220-1, 220-2 similar to frequency tuning element 220 described in relation to FIG. 2 can be connected serially via a single global flux line 240.

Each frequency tuning element 220-1, 220-2 is coupled to at least one tuning line (respectively 203-1 and/or 204-1, 203-2 and/or 204-2) to control an associated quantum device (respectively 101-1, 101-2). The frequency of each quantum device 101-1, 101-2 can be independently adjusted by tuning the associated MJJ (respectively 202-1, 202-2) via the associated tuning lines (respectively 203-1 and/or 204-1, 203-2 and/or 204-2).

Since the plurality of frequency tuning elements 220-1, 220-2 are driven by the single global flux line 240, such an implementation can reduce the total number of global flux lines needed.

Although the embodiment of FIG. 4 illustrates only two frequency tuning elements 220-1, 220-2 connected serially, this is only for clarity of illustration. There may be any number of frequency tuning elements 220 connected serially via a single global flux line 240.

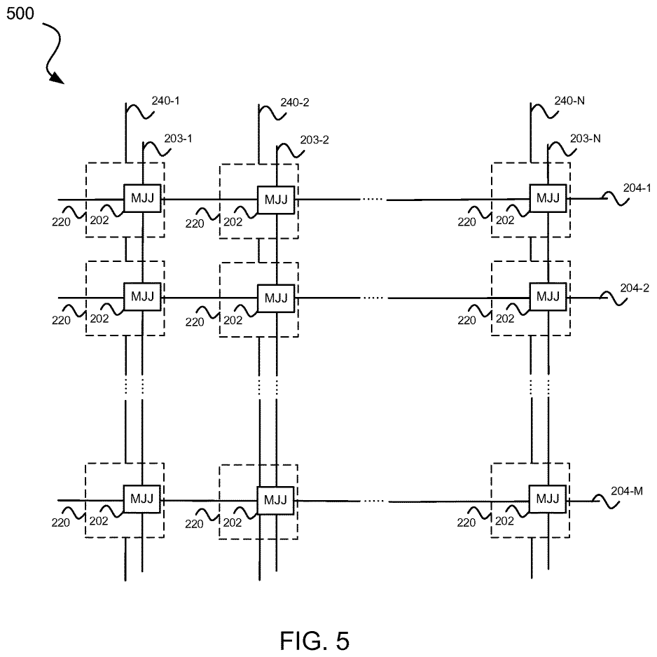

As illustrated by FIG. 5, the tuning lines 203 and 204 can be arranged in a cross-bar architecture. Such an implementation can reduce the number of tuning lines needed. As such, crosstalk and/or heating can be further reduced. This also enables QPU scaling.

FIG. 5 illustrates an arrangement 500 comprising a plurality of global flux lines 240-1, 240-2, 240-N. A plurality of frequency tuning elements 220 is connected in series to each global flux line 240-1, 240-2, 240-N. Each frequency tuning element 220 is configured to control one quantum device 101 of a plurality of quantum devices 101.

The arrangement 500 comprises a plurality of first tuning lines 203-1, 203-2, 203-N and a plurality of second tuning lines 204-1, 204-2, 204-M. For example, for an arrangement comprising N×M frequency tuning elements 220, the arrangement 500 may comprise N first tuning lines 203-1, 203-2, 203-N and M second tuning lines 204-1, 204-2, 204-M. All the first and second tuning lines 203, 204 may be connected to a same frequency tuning unit 130.

Each frequency tuning element 220 is coupled to one of the first tuning lines 203 and one of the second tuning lines 204. The first and second tuning lines are arranged in a cross-bar pattern. By applying signals of required amplitude and duration, a magnetic field of required strength can be applied to the free layer 304 of the MJJ 202. This ensures that the current I_{M} can be changed to the required value. As such, each frequency tuning element 220 can be individually controlled by the frequency tuning unit 130 to tune the frequency of the associated quantum device.

The MJJ 202 may be placed in series with one or more shunt resistors and/or in series with an inductor to adjust its dynamic properties.

FIG. 6 illustrates a schematic representation of a quantum device 101 and a frequency tuning element 620 according to another embodiment.

In the embodiment of FIG. 6, the spintronic device (SD) 602 is configured to generate the magnetic field that induces the magnetic flux 610 through the quantum device 101. The spintronic device 602 may be, for example, a magnetic tunnel junction—MTJ—, or a spin valve.

The quantum device 101 is magnetically coupled to the spintronic device 602. In some embodiments, the quantum device 101 and the spintronic device 602 are coupled via a flux transformer.

In some embodiments, the quantum device 101 and the spintronic device 602 are based on a flip-chip design. The spintronic device 602 is placed on a first substrate 605. The quantum device 101 is placed on a second substrate 606. In some embodiments, the spintronic device 602 and the quantum device 101 are on different layers of a same substrate. In some embodiments, the spintronic device 602 and the quantum device 101 are placed on opposite sides of a substrate.

The strength of the magnetic flux 610 through the quantum device 101 depends on the state of the spintronic device 602. Since the spintronic device 602 retains its magnetic properties, the spintronic device 602 needs to be tuned only once to adjust and maintain the frequency of the quantum device 101.

The spintronic device 602 is electrically coupled to at least one tuning line 103 (e.g., tuning lines 603 and 604). The tuning signal can be applied to the spintronic device 602 as a non-persistent current applied via the tuning line 603 and/or 604.

More specifically, the frequency of the quantum device 101 can be adjusted from an initial value to a required value by tuning the spintronic device 602. The spintronic device 602 can be tuned by applying the non-persistent current to the spintronic device 602. The strength of the magnetic flux 610 through the quantum device is consequently adjusted to a required value. This causes the frequency of the quantum device 101 to shift from an initial value to a required value.

The spintronic device 602 exhibits memristive behaviour in the sense that it can be tuned continuously within a range and can retain its magnetic properties after being tuned. As such, once the spintronic device 602 is tuned, it generates persistent stray fields even after the tuning signal is applied. Thus, the magnetic flux 610 through the quantum device 101 can be maintained at the adjusted strength after the non-persistent tuning signal is applied. As such, the frequency tuning element 620 can shift the operational frequency of the quantum device 101 from the initial state to the desired state and maintain the operational frequency of the quantum device 101 at the desired state after the non-persistent tuning signal is applied.

FIG. 7 illustrates a schematic representation of the spintronic device 602 according to an embodiment. In particular, the spintronic device may be a magnetic tunnel junction (MTJ), or a spin valve (SV).

The spintronic device 602 comprises a magnetic free layer 704. The magnetic free layer 704 may be perpendicularly magnetised. In some embodiments, the spintronic device 602 also comprises a magnetic fixed layer 705. In some embodiments, the magnetic layers 704 and 705 are separated by a barrier 703, also called tunnel junction. The barrier 703 can be a thin insulating barrier (e.g., thin oxide layer), or a thin layer of normal metal in case of a spin valve.

The spintronic device 602 may further comprise two metallic (e.g., made of superconducting and/or heavy metal) electrodes 701, 702. The electrodes 701, 702 are each connected to one of the tuning lines 603, 604 such that the tuning signal can be applied as a current to the spintronic device 602 via the electrodes 701, 702. The spintronic device 602 generates a persistent magnetic field even when no current is applied to the electrodes 701, 702.

The orientation of magnetization of the magnetic layer 704 (e.g., the relative orientation of magnetisation of the layers 704 and 705) determines the state of the spintronic device 602, and therefore the strength of the magnetic field generated by the spintronic device 602.

The spintronic device 602 can be tuned by applying a non-persistent current to the spintronic device 602 via the electrodes 701, 702. Consequently, the orientation of magnetization of the layer 704 (e.g., the relative orientation of the layers 704 and 705, and therefore the magnetic field generated by the spintronic device 602 is correspondingly adjusted.

The spintronic device tuning may be achieved using the spin-transfer torque (STT) effect arising from the current applied via the electrodes 701, 702 flowing through the junction. Spin-transfer torque is an effect in which the relative orientation of magnetization of the layers is modified using a spin-polarized current. A spin-polarised current may be generated by flowing a current through either of the magnetic layers 704, 705. This spin-polarised current can hence be used to transfer angular momentum from the fixed layer 705 to the free layer 704 and vice versa. Using the direction of the applied current, the free layer 704 can be switched in either direction, as needed. An example of such a spintronic device is described in Bhatti, S. “Spintronics based random access memory: a review,” Materials Today 20, 530, 2017.

The magnetic free layer 704 may be made from a granular media. Such a granular free layer can provide memristic behavior, as for example described in in M. Mansueto, “Memristic magnetic memory for spintronic synapses,” Universite Grenoble Alpes, 2020.

The spintronic device may be a magnetic tunnel junction—MTJ—602. The MTJ 602 exhibits spin-transfer torque memory, in the sense that it retains the relative orientation of magnetization of the layers after the tuning signal is applied. An example of such a MTJ is described in Jenkins, S. “Magnetic stray fields in nanoscale magnetic tunnel junctions,” J. Phys. D: Appl. Phys. 53, 044001, 2020.

The spintronic device tuning may be achieved using spin-orbit torque (SOT) exerted on the free layer 704 when a current flows through the electrode 701. This is also called the phenomena of spin Hall effect. In this case, the barrier 703 is made of an insulating material to ensure that the current does not flow through the barrier. The fixed layer 705 in this case consists of an in-plane magnetised magnetic layer. The in-plane magnetised fixed layer 705 is used to break the symmetry of switching, enabling the tuning of the free layer 704 in either direction, as described, for example, in Krizakova, V. “Field-free switching of magnetic tunnel junctions driven by spin-orbit torques at sub-ns timescales,” Appl. Phys. Lett. 16, 232406, 2020. The direction of tuning can also be determined using the shape of this magnetic element as described, for example, in Safeer, C. K., “Spin-orbit torque magnetisation switching controlled by geometry,” Nat. Na-no. 11, 143, 2016 or a symmetry breaking electromagnetic field provided by the electrode 702. The use of barrier 703 or fixed layer 705 is not strictly necessary for spin-orbit torque based MTJ tuning.

The memristive behaviour may be achieved using the domain wall motion of the free layer, as described, for example, in Lequeux, S. “A magnetic synapse: multi-level spin-torque memristor with perpendicular anisotropy, ” Sci. Rep. 6, 31510, 2016.

The spintronic device tuning can be achieved using domain wall (DW) motion in the magnetic media of the free layer 704, as described, for example, in Boulle, O. et. al., “Current-induced domain wall motion in nanoscale magnetic elements”, Mat. Sci. and Eng.: R: Rep. 72, 159, 2011.

The domain wall motion can be achieved by applying a current through tuning line 603. In that case, tuning line 603 may be connected directly to the perpendicularly magnetized magnetic free layer 704, or via the layer 701 (e.g., which may consist of platinum) in order to enable the perpendicular anisotropy of the free layer 704 and could contribute to the domain wall motion by spin-orbit torques as well). The flow of electrons through the free layer 704 exerts a spin torque on the domain wall, moving it, and changing the effective magnetic field produced by the spintronic device 602.

The domain wall motion may also be achieved by the magnetic field induced by a current flowing in the tuning line 604 connected to the electrode 702. In this case, the fixed layer is not strictly necessary, and the electrode 702 is electrically isolated from the free layer 704. Here, the domain wall can be initialised using the geometry of the free layer 704 and/or by a magnetic field induced by the current flowing in the tuning line 604 connected to electrode 702 and/or using a global magnetic field. The memristive behaviour may be achieved using local defects in the film leading to inherent pinning sites or by the use of granular media for the free layer 704.

The spintronic device tuning can be achieved using a combination of spin-orbit torque (SOT), spin-transfer torque (STT), and/or domain wall motion (DW).

For example, in the case of an electrode 605 made of normal or light metal, the spintronic device may be driven by STT. The current may actually pass through the MTJ. In the case of an electrode 605 605 made of heavy metal, the driving mechanism may be a combination of SOT and DW. The current may flow only along the electrode 605 and does not have to pass through the MTJ. The use of the electrode 605 is not strictly necessary.

The use of the fixed layer (e.g., in the case of a MTJ, or an SV) is only necessary for the ability to rotate or switch the free layer magnetisation in either direction: by reflecting the minority spin current (for STT) and by providing a symmetry breaking field (for SOT).

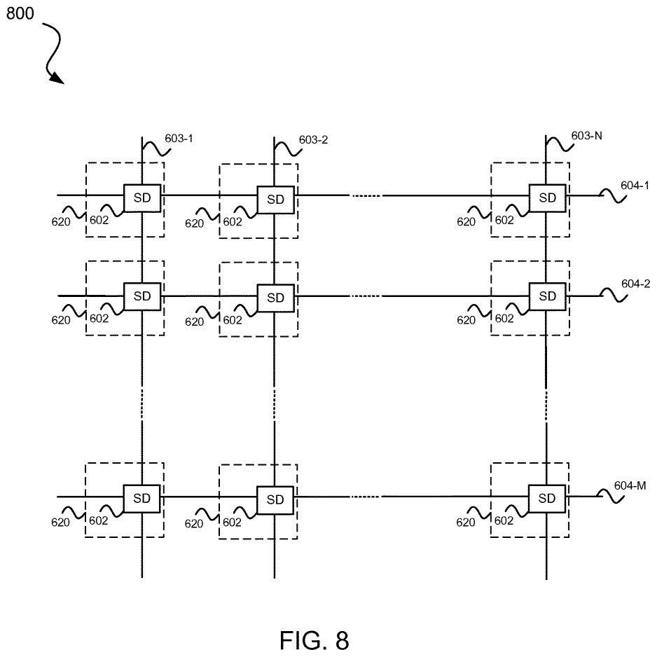

As illustrated by FIG. 8, the tuning lines 603 and 604 can be arranged in a cross-bar architecture. Such an implementation can reduce the number of tuning lines needed. As such, crosstalk and/or heating can be further reduced. This also enables QPU scaling.

FIG. 8 illustrates an arrangement 800 comprising a plurality of first tuning lines 603-1, 603-2, 603-N and a plurality of second tuning lines 604-1, 604-2, 604-M. For example, for an arrangement comprising N×M frequency tuning elements 620, the arrangement 800 may comprise N first tuning lines 603-1, 603-2, 603-N and M second tuning lines 604-1, 604-2, 604-M. All the first and second tuning lines 603, 604 may be connected to a same frequency tuning unit 130.

An electric connection between the tuning lines and the spintronic device 602 may comprise any number of electrical components, such as capacitors, etc.

Each frequency tuning element 620 is coupled to one of the first tuning lines 603 and one of the second tuning lines 604. The first and second tuning lines are arranged in a cross-bar pattern. As such, each frequency tuning element 620 can be individually controlled by the frequency tuning unit 130 to tune the frequency of the associated quantum device.

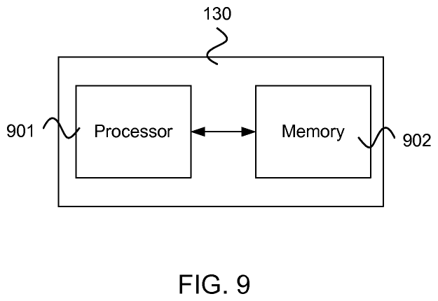

FIG. 9 illustrates a schematic representation of a tuning unit 130 according to an embodiment.

The tuning unit 130 may be configured to generate and/or control one or more tuning signals provided to one or more frequency tuning elements 120.

The tuning unit 130 may comprise at least one processor 901. The at least one processor 901 may comprise, for example, one or more of various processing devices, such as a co-processor, a microprocessor, a digital signal processor (DSP), a processing circuitry with or without an accompanying DSP, or various other processing devices including integrated circuits such as, for example, an application specific integrated circuit (ASIC), a field programmable gate array (FPGA), a microprocessor unit (MCU), a hardware accelerator, a special-purpose computer chip, or the like.

The tuning unit 130 may further comprise a memory 902. The memory 902 may be configured to store, for example, computer programs, signal waveform patterns, and the like. The memory 902 may comprise one or more volatile memory devices, one or more non-volatile memory devices, and/or a combination of one or more volatile memory devices and non-volatile memory devices. For example, the memory 902 may be embodied as magnetic storage devices (such as hard disk drives, magnetic tapes, etc.), optical magnetic storage devices, and semiconductor memories (such as mask ROM, PROM (programmable ROM), EPROM (erasable PROM), flash ROM, RAM (random access memory), etc. ).

The tuning unit 130 may further comprise other components not illustrated in the embodiment of FIG. 9. The tuning unit 130 may comprise, for example, an input/output bus for connecting the tuning unit 130 to other devices. Further, a user may control the tuning unit 130 via the input/output bus. The user may, for example, control quantum computation operations performed by the arrangement 100 via the tuning unit 130 and the input/output bus.

The tuning unit 130 may further comprise multiplexers and de-multiplexers to provide fan-in/fan-out functionality. The tuning unit 130 may further comprise switches leading to tuning lines to enable the turning ON and OFF of the signals, especially to facilitate the arrangement of the tuning lines in a cross-bar pattern.

The tuning unit 130 may further comprise appropriate signal sources for generating and controlling the tuning signals. For example, the tuning unit 130 may comprise at least one RF signal source and/or at least one optical signal source, such as at least one laser.

When the tuning unit 130 is configured to implement some functionality, some component and/or components of the tuning unit 130, such as the at least one processor 901 and/or the memory 902, may be configured to implement this functionality. Furthermore, when the at least one processor 901 is configured to implement some functionality, this functionality may be implemented using program code comprised, for example, in the memory.

The tuning unit 130 may be implemented at least partially using, for example, a computer, some other computing device, or similar.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An arrangement for frequency tuning at least one quantum device, wherein the arrangement comprises a frequency tuning element, wherein the frequency tuning element is configured to generate a magnetic flux through the quantum device, characterized in that the frequency tuning element comprises:
a spintronic device, wherein the spintronic device comprises a magnetic free layer, wherein the frequency tuning element is configured to adjust an orientation of a magnetization of the magnetic free layer, thereby adjusting the strength of the magnetic flux through the quantum device, and causing the operational frequency of the quantum device to shift.

2. An arrangement according to claim 1, wherein the spintronic device further comprises a magnetic fixed layer separated from the magnetic free layer.

3. An arrangement according to claim 2, the arrangement further comprising a frequency tuning unit, and at least one tuning line coupled to the spintronic device, wherein the frequency tuning unit is configured to apply a non-persistent signal to the spintronic device via the tuning line to adjust the orientation of the magnetization of the magnetic free layer, thereby adjusting the strength of the magnetic flux through the quantum device, and causing the operational frequency of the quantum device to shift.

4. An arrangement according to claim 3, wherein the spintronic device comprises a Magnetic Josephson Junction (MJJ),
wherein the arrangement further comprises a global flux line connected to a constant current source, and
wherein the frequency tuning element comprises a current divider of the global flux line, the current divider comprising a first branch and a second branch, wherein
the first branch comprises an inductive element coupled to the quantum device such that a flux current (I_{F}) going through the inductive element generates the magnetic flux through the quantum device, and
the second branch comprises the MJJ, wherein the tuning line, is magnetically coupled to the MJJ, wherein the frequency tuning unit is configured to apply a non-persistent magnetic field to the MJJ via the tuning line to adjust the orientation of the magnetization of the magnetic free layer, thereby adjusting a current (I_{M}) that passes through the MJJ, thereby adjusting the flux current (I_{F}) going through the inductive element, thereby adjusting the strength of the magnetic flux through the quantum device, and causing the operational frequency of the quantum device to shift.

5. An arrangement according to claim 4, the arrangement comprising a plurality of global flux lines, wherein a plurality of frequency tuning elements is serially connected to each global flux line.

6. An arrangement according to claim 5, wherein the magnetic free layer is an in-plane magnetised isotropically coercive layer.

7. An arrangement according to claim 5, wherein the magnetic free layer is made from a granular media.

8. An arrangement according to claim 7, wherein the inductive element is coupled to the quantum device via a flux transformer.

9. An arrangement according to claim 8, wherein
the inductive element and the quantum device are placed on opposite sides of a substrate;
the inductive element and the quantum device are placed on a same side of a substrate; or
the inductive element and the quantum device are placed on two different substrates, wherein the inductive element and the quantum device are optionally coupled via a galvanic link.

10. An arrangement according to claim 9, wherein the MJJ is placed in series with a shunt resistor.

11. An arrangement according to claim 3, wherein the spintronic device is configured to generate the magnetic flux through the quantum device, and wherein the frequency tuning unit is configured to apply a non-persistent current to the spintronic device via the tuning line to adjust the orientation of the magnetization of the magnetic free layer, thereby adjusting the strength of the magnetic flux through the quantum device, and causing the operational frequency of the quantum device to shift.

12. An arrangement according to claim 11, wherein the magnetic free layer is made from a granular media to provide memristive behavior.

13. An arrangement according to claim 12, wherein the spintronic device is configured to adjust the orientation of the magnetization of the magnetic free layer via spin-transfer torque effect.

14. An arrangement according to claim 13, wherein the spintronic device is configured to adjust the orientation of the magnetization of the magnetic free layer via spin-orbit torque effect.

15. An arrangement according to claim 14, wherein the spintronic device is configured to adjust the orientation of the magnetization of the magnetic free layer via domain wall motion.

16. An arrangement according to claim 15, wherein the spintronic device is a magnetic spin valve.

17. An arrangement according to claim 15, wherein the spintronic device is a magnetic tunnel junction (MTJ).

18. An arrangement according to claim 17, wherein
the spintronic device and the quantum device are placed on opposite sides of a substrate;
the spintronic device and the quantum device are placed on a same side of a substrate; or
the spintronic device and the quantum device are placed on two different substrates, wherein the spintronic device and the quantum device are optionally coupled via a galvanic link.

19. An arrangement according to claim 18, wherein the quantum device and the spintronic device are coupled via a flux transformer.

20. An arrangement according to claim 1, wherein the at least one quantum device comprises one or more of at least one qubit or at least one tunable coupler.

21. A quantum computing system, comprising a plurality of quantum devices, and at least an arrangement according to claim 1 for tuning the operational frequency of at least one of the quantum devices.

22. A quantum computing system according claim 21, the quantum computing system further comprising a global magnetic field coil configured to reset one or more of the spintronic devices.

23. A quantum computing system according to claim 22, wherein:
said plurality of quantum devices form an array, and;
the spintronic device of each frequency tuning element is coupled to two tuning lines, and wherein the tuning lines of all the frequency tuning elements are placed in a cross-bar architecture.

24. A method for frequency tuning one or more quantum devices in a quantum computing system according to claim 23, the method comprising:
adjusting the orientation of magnetization of the magnetic free layer, thereby adjusting the strength of the magnetic flux through the quantum device and causing the operational frequency of the quantum device to shift.
